(19) United States
(12) Patent Application Publication
(10) Pub. No.: US 2020/0394954 A1
(43) Pub. Date: Dec. 17, 2020

(54) DRIVING APPARATUS AND OPERATION METHOD THEREOF

(71) Applicant: Novatek Microelectronics Corp., Hsinchu (TW)

(72) Inventors: Hongchun Cong, Xi'an City (CN); YuanJia Du, Shandong Province (CN)

(73) Assignee: Novatek Microelectronics Corp., Hsinchu (TW)

(21) Appl. No.: 16/454,067

(22) Filed: Jun. 27, 2019

(30) Foreign Application Priority Data
Jun. 14, 2019 (CN) 201910515610.8

(51) Int. Cl. G09G 3/3208; H01L 27/32

(52) U.S. Cl. CPC G09G 3/3208; H01L 27/3213; G09G 2320/0626; G09G 2320/0233; G09G 2320/046

(57) ABSTRACT

A driving apparatus and an operation method thereof are provided. The driving apparatus is used to drive a display panel. The driving apparatus includes a first dynamic adjustment circuit and a second dynamic adjustment circuit. The first dynamic adjustment circuit dynamically adjusts a dynamic value. The first dynamic adjustment circuit changes first color original data according to the dynamic value to obtain first color new data. The second dynamic adjustment circuit is coupled to the first dynamic adjustment circuit to receive the dynamic value. The second dynamic adjustment circuit changes second color original data according to the dynamic value to obtain second color new data, so as to compensate a brightness difference between the first color new data and the first color original data.

### CROSS-REFERENCE TO RELATED APPLICATION

This application claims the priority benefit of China application serial no. 201910515610.8, filed on Jun. 14, 2019. The entirety of the above-mentioned patent application is hereby incorporated by reference herein and made a part of this specification.

### BACKGROUND

### Field of the Invention

The invention relates to a display apparatus and more particularly, to a driving apparatus and an operation method thereof.

### Description of Related Art

Some types of display panels may have a phenomenon of image sticking. For example, in an organic light emitting diode (OLED) display panel, the image sticking may occur to the OLED display panel after displaying a still object for a time period. This phenomenon is a so-called burn-in (or referred to as burn-down) phenomenon. The OLED display panel has an organic compound film. As a duration of the OLED display panel used is increased, and heat is generated, an organic material thereof is gradually aged. The image sticking of the OLED display panel actually refers to a same still image displayed by some pixels in a certain fixed position on a screen for a long time, which causes the aging of the organic compound film corresponding to the pixels to be faster than pixels in other positions. These rapidly aged pixels leave the image sticking on the screen. Generally, the burn-in phenomenon is irreversible. How to prevent the occurrence of the burn-in phenomenon is an important subject to the technical field related to display apparatuses.

It should be noted that the contents of the section of “Description of Related Art” is used for facilitating the understanding of the invention. A part of the contents (or all of the contents) disclosed in the section of “Description of Related Art” may not pertain to the conventional technology known to the persons with ordinary skilled in the art. The contents disclosed in the section of “Description of Related Art” do not represent that the contents have been known to the persons with ordinary skilled in the art prior to the filing of this invention application.

### SUMMARY

The invention provides a driving apparatus and an operation method thereof to reduce a probability of the occurrence of the burn-in phenomenon.

According to an embodiment of the invention, a driving apparatus configured to drive a display panel is provided. The driving apparatus includes a first dynamic adjustment circuit and a second dynamic adjustment circuit. The first dynamic adjustment circuit is configured to receive first color original data and dynamically adjust a dynamic value. The first dynamic adjustment circuit changes the first color original data according to the dynamic value to obtain first color new data, wherein the first color new data is used to drive a first color sub-pixel of a pixel of the display panel. The second dynamic adjustment circuit is coupled to the first dynamic adjustment circuit to receive the dynamic value. The second dynamic adjustment circuit is configured to receive second color original data. The second dynamic adjustment circuit changes the second color original data according to the dynamic value to obtain second color new data, so as to compensate a brightness difference between the first color new data and the first color original data, wherein the second color new data is used to drive a second color sub-pixel of the pixel of the display panel.

According to an embodiment of the invention, an operation method of a driving apparatus is provided. The driving apparatus is configured to drive a display panel. The operation method includes: dynamically adjusting a dynamic value by a first dynamic adjustment circuit; changing first color original data according to the dynamic value by the first dynamic adjustment circuit to obtain first color new data, wherein the first color new data is used to drive a first color sub-pixel of a pixel of the display panel; receiving the dynamic value of the first dynamic adjustment circuit by a second dynamic adjustment circuit; and changing second color original data according to the dynamic value by the second dynamic adjustment circuit to obtain second color new data, so as to compensate a brightness difference between the first color new data and the first color original data, wherein the second color new data is used to drive a second color sub-pixel of the pixel of the display panel.

To sum up, the driving apparatus and the operation method provided by the embodiments of the invention can change the first color original data according to the dynamic value to obtain the first color new data, thereby reducing the probability of the burn-in phenomenon occurring to the first color sub-pixel. In addition, the driving apparatus can also change the second color original data of the second color sub-pixel to the second color new data according to the dynamic value, so as to compensate the brightness difference between the first color new data and the first color original data.

To make the above features and advantages of the invention more comprehensible, embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic circuit block diagram illustrating a driving apparatus according to an embodiment of the invention.

FIG. 2 is a flowchart illustrating an operation method of a driving apparatus according to an embodiment of the invention.

FIG. 3 is a schematic diagram illustrating a time curve according to an embodiment of the invention.

### DESCRIPTION OF EMBODIMENTS

The term “couple (or connect)” throughout the specification (including the claims) of this application are used broadly and encompass direct and indirect connection or coupling means. For example, if the disclosure describes a first apparatus being coupled (or connected) to a second apparatus, then it should be interpreted that the first apparatus can be directly connected to the second apparatus, or the first apparatus can be indirectly connected to the second apparatus through other devices or by a certain coupling means. In addition, terms such as “first” and “second” mentioned throughout the specification (including the claims) of this application are only for naming the names of the elements or distinguishing different embodiments or scopes and are not intended to limit the upper limit or the lower limit of the number of the elements not intended to limit sequences of the elements. Moreover, elements/components/steps with same reference numerals represent same or similar parts in the drawings and embodiments. Elements/components/notations with the same reference numerals in different embodiments may be referenced to the related description.

Some types of display panels may have a phenomenon of image sticking. For example, an image sticking phenomenon may occur to an OLED display panel after OLED display panel displays a still object for a long time, and this phenomenon is a so-called burn-in (or referred to as burn-down) phenomenon. How to prevent the occurrence of the burn-in phenomenon is an important subject to the technical field related to display apparatuses. In some embodiments, for a pixel which the burn-in phenomenon likely occurs to, a probability of the occurrence of the burn-in phenomenon may be effectively reduced by adaptively reducing a pixel brightness. The lower the brightness is, the less heat the pixel generates. In this way, the probability of the occurrence of the burn-in phenomenon may be reduced.

In anyway, the reduction of the pixel brightness means the reduction of an image brightness. For a still image scene, the way to reduce the pixel brightness may be available. However, the way to reduce the pixel brightness is not applicable to a motion video.

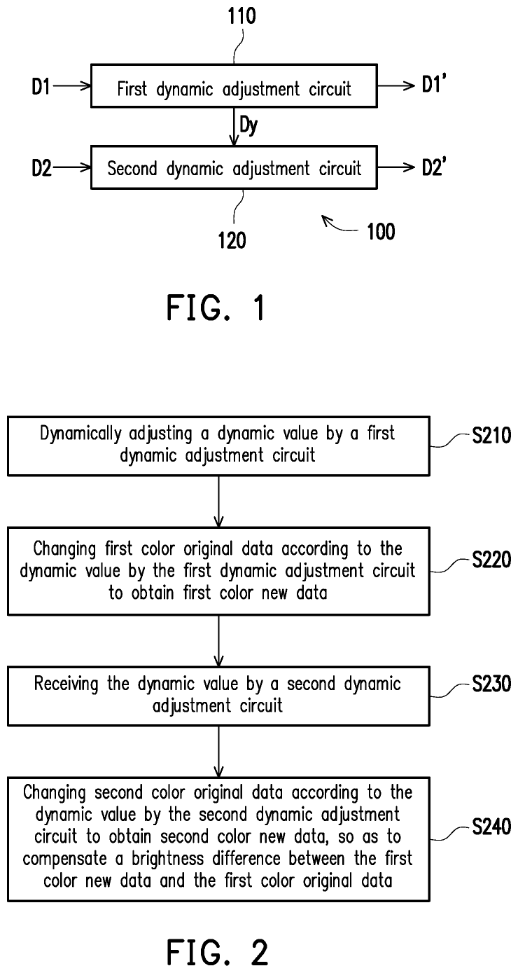

FIG. 1 is a schematic circuit block diagram illustrating a driving apparatus 100 according to an embodiment of the invention. The driving apparatus 100 illustrated in FIG. 1 may drive a display panel (not shown) to display an image. Based on a design requirement, the display panel may be an OLED display panel or other types of display panels.

In the embodiment illustrated in FIG. 1, the driving apparatus 100 includes a first dynamic adjustment circuit 110 and a second dynamic adjustment circuit 120. The first dynamic adjustment circuit 110 is configured to receive first color original data D1 and generate first color new data D1′ according to the first color original data D1. The second dynamic adjustment circuit 120 is configured to receive second color original data D2 and generate second color new data D2′ according to the second color original data D2. The driving apparatus 100 may drive a first color sub-pixel and a second color sub-pixel of a certain pixel of the display panel (not shown) according to the first color new data D1′ and the second color new data D2′. The driving manner performed on the display panel (not shown) by the driving apparatus 100 is not limited in the present embodiment. Based on a design requirement, in some embodiments, the driving apparatus 100 may be disposed with a conventional driving circuit (not shown) or other driving circuits, and the conventional drive circuit (or other driving circuits) may use the first color new data D1′ and the second color new data D2′ to drive the display panel (not shown) to display an image.

FIG. 2 is a flowchart illustrating an operation method of a driving apparatus according to an embodiment of the invention. Referring to FIG. 1 and FIG. 2, in step S210, the first dynamic adjustment circuit 110 may dynamically adjust a dynamic value Dy. The manner for generating the dynamic value Dy is not limited in the present embodiment. Based on a design requirement, in some embodiments, the dynamic value Dy may be a pseudo random number that is not related to the first color original data D1 and the second color original data D2 and limited to an adaptation range. The adaptation range may be determined based on a design requirement. In some other embodiments, the dynamic value Dy may be a dynamic real number related to the first color original data D1 and/or the second color original data D2. For example, the first dynamic adjustment circuit 110 may calculate the dynamic value Dy by using the second color original data D2 and a certain time curve (or a pseudo random number). A value of the time curve varies with the time. The time curve may be determined based on a design requirement.

In step S220, the first dynamic adjustment circuit 110 may change the first color original data D1 according to the dynamic value Dy to obtain the first color new data D1′, wherein the first color new data D1′ is used to drive a first color sub-pixel of a certain target pixel of the display panel (not shown). For example (but not limited to), the first color original data D1 may be sub-pixel data (e.g., grayscale data) corresponding to a white sub-pixel of the OLED display panel (not shown). The driving apparatus 100 may drive the white sub-pixel of the OLED display panel (not shown) according to the first color new data D1′.

The first dynamic adjustment circuit 110 may change the first color original data D1 according to the dynamic value Dy to obtain the first color new data D1′. Thus, a brightness of the sub-pixel corresponding to the first color original data D1 may be effectively reduced. During a process of the display panel displaying the still image for a long time, for a sub-pixel which the burn-in phenomenon likely occurs to, the brightness of the sub-pixel may be adaptively reduced. The lower the brightness is, the less heat the sub-pixel generates. In this way, the probability of the occurrence of the burn-in phenomenon may be reduced.

The second dynamic adjustment circuit 120 is coupled to the first dynamic adjustment circuit 110 to receive the dynamic value Dy (step S230). In step S240, the second dynamic adjustment circuit 120 may change the second color original data D2 according to the dynamic value Dy to obtain the second color new data D2′, wherein the second color new data D2′ is used to drive a second color sub-pixel of the target pixel of the display panel (not shown). For example (but not limited to), the second color original data D2 may be sub-pixel data (e.g., grayscale data) corresponding to a non-white sub-pixel (e.g., a red sub-pixel, a green sub-pixel or a blue sub-pixel) of the OLED display panel (not shown). If the second color original data D2 is grayscale data corresponding to a red sub-pixel, the driving apparatus 100 may drive the red sub-pixel of the OLED display panel (not shown) according to the first color new data D1′. The green sub-pixel and the blue sub-pixel may be inferred with reference to the description related to the red sub-pixel and will not be repeated.

It should be noted that the second dynamic adjustment circuit 120 may change the second color new data D2′, so as to compensate a brightness difference between the first color new data D1′ and the first color original data D1. Namely, even though the brightness of the sub-pixel corresponding to the first color original data D1 is reduced, the second dynamic adjustment circuit 120 may increase the brightness of the sub-pixel corresponding to the second color original data D2. Thus, the brightness of the target pixel may be substantially maintained.

For example, when the OLED display panel (not shown) displays a still image with a high brightness and a low saturation degree, the burn-in phenomenon may likely occur to such still image. By the operation method illustrated in FIG. 2, the driving apparatus 100 may reduce a brightness of the white sub-pixel of the OLED display panel, thereby reducing the probability of the burn-in phenomenon occurring to the white sub-pixel. In a condition that the brightness of the white sub-pixel is reduced, the driving apparatus 100 may increase the brightness of one or more of the red sub-pixel, the green sub-pixel and the blue sub-pixel, so as to compensate the reduced brightness of the white sub-pixel. Thus, the white sub-pixel may be protected, while the high brightness required by the still image displayed by the OLED display panel (not shown) may be maintained. The driving apparatus 100 may be applicable to a motion video.

Hereinafter, it is assumed that the first color original data D1 includes white original data (sub-pixel data) Win corresponding to the white sub-pixel of the OLED display panel (not shown), and the second color original data D2 includes sub-pixel data Rin corresponding to the red sub-pixel, sub-pixel data Gin corresponding to the green sub-pixel, sub-pixel data Bin corresponding to the blue sub-pixel of the OLED display panel (not shown). The first dynamic adjustment circuit 110, in step S210, may dynamically adjust the dynamic value Dy according to a time curve. For example, the first dynamic adjustment circuit 110 may obtain the dynamic value Dy by calculating Formula 1 below. Namely, the first dynamic adjustment circuit 110 may obtain the dynamic value Dy by multiplying an offset value Woffset by a ratio Rf.

Dy=Woffset*Rf Formula 1

In some embodiments, the offset value Woffset shown in Formula 1 may be a fixed real number determined based on a design requirement. In some other embodiments, the offset value Woffset may be related to a difference between the first color original data D1 and the second color original data D2. Alternatively, the offset value Woffset may be related to a difference between a maximum among the red original data Rin, the green original data Gin and the blue original data Bin and the first color original data D1. For example, the offset value Woffset may be obtained by calculating Formula 2. In Formula 2, a coefficient R1 may be determined based on a design requirement. For example, in some application examples, the coefficient R1 may be a real number related to the maximum among the red original data Rin, the green original data Gin and the blue original data Bin.

Woffset=(Win−MAX(Rin, Gin, Bin))*R1 Formula 2

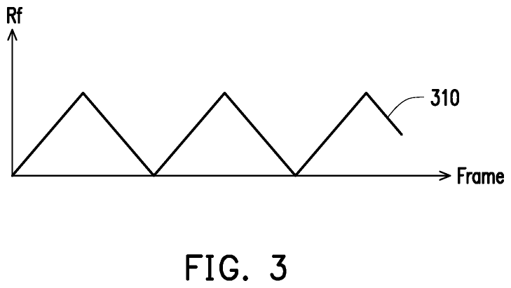

The first dynamic adjustment circuit 110 may determine the ratio Rf in Formula 1 according to a certain time curve. The time curve may be determined based on a design requirement. As an example for illustration, FIG. 3 is a schematic diagram illustrating a time curve 310 according to an embodiment of the invention. In FIG. 3, the horizontal axis represents image frames, and the vertical axis represents values of the ratio Rf. In a condition that the first dynamic adjustment circuit 110 uses the time curve 310 illustrated in FIG. 3, the dynamic value Dy has different values in different frames.

The first dynamic adjustment circuit 110, in step S220, may change the first color original data D1 according to the dynamic value Dy to obtain the first color new data D1′. For example, the first dynamic adjustment circuit 110 may subtract the white original data Win (i.e., the first color original data D1) by the dynamic value Dy to obtain white new data Wout (i.e., the first color new data D1′), as shown by Formula 3.

Wout=Win−Dy Formula 3

The second dynamic adjustment circuit 120, in step S240, may add the second color original data D2 by the dynamic value Dy to obtain the second color new data D2′. For example, the second dynamic adjustment circuit 120 may add the red original data Rin by the dynamic value Dy to obtain red new data Rout (as presented by Formula 4), add the green original data Gin by the dynamic value Dy to obtain green new data Gout (as presented by Formula 5), and add the blue original data Bin by the dynamic value Dy to obtain blue new data Bout (as presented by Formula 6). In the present embodiment, the second color new data D2′ illustrated in FIG. 1 may include the red new data Rout, the green new data Gout and the blue new data Bout.

Rout=Rin+Dy Formula 4

Gout=Gin+Dy Formula 5

Bout=Bin+Dy Formula 6

In light of the foregoing, the first dynamic adjustment circuit 110 may change the white original data D1 according to the dynamic value Dy to obtain the white new data Wout. Thus, the brightness of the white sub-pixel may be effectively reduced. An aging speed of the white sub-pixel may be effectively slowed down by adaptively reducing the brightness of the white sub-pixel, so as to reduce the probability of the occurrence of the burn-in phenomenon. An amount that the brightness of the white new data Wout is reduced may be compensated by increasing the brightness of the red new data Rout, the brightness of the green new data Gout and the brightness of the blue new data Bout. In the same target pixel, even though the brightness of the white sub-pixel is reduced, the brightness of the red, the green and the blue pixels may be correspondingly increased, and thus, the brightness of the target pixel may be substantially maintained.

Based on different design demands, the blocks of the first dynamic adjustment circuit 110 and/or the second dynamic adjustment circuit 120 may be implemented in a form of hardware, firmware, software (i.e., programs) or in a combination of many of the aforementioned three forms.

In terms of the hardware form, the blocks of the image superimposing circuit 110 and/or the fingerprint matching circuit 120 may be implemented in a logic circuit on an integrated circuit. Related functions of the first dynamic adjustment circuit 110 and/or the second dynamic adjustment circuit 120 may be implemented in a form of hardware by utilizing hardware description languages (e.g., Verilog HDL or VHDL) or other suitable programming languages. For example, the related functions of the first dynamic adjustment circuit 110 and/or the second dynamic adjustment circuit 120 may be implemented in one or more controllers, micro-controllers, microprocessors, application-specific integrated circuits (ASICs), digital signal processors (DSPs), field programmable gate arrays (FPGAs) and/or various logic blocks, modules and circuits in other processing units.

In terms of the software form and/or the firmware form, the related functions of the first dynamic adjustment circuit 110 and/or the second dynamic adjustment circuit 120 may be implemented as programming codes. For example, the first dynamic adjustment circuit 110 and/or the second dynamic adjustment circuit 120 may be implemented by using general programming languages (e.g., C or C++) or other suitable programming languages. The programming codes may be recorded/stored in recording media. The aforementioned recording media include, for example, a read only memory (ROM), a storage device and/or a random access memory (RAM). Additionally, the programming codes may be accessed from the recording medium and executed by a computer, a central processing unit (CPU), a controller, a micro-controller or a microprocessor to accomplish the related functions. As for the recording medium, a non-transitory computer readable medium, such as a tape, a disk, a card, a semiconductor memory or a programming logic circuit, may be used. In addition, the programs may be provided to the computer (or the CPU) through any transmission medium (e.g.., a communication network or radio waves). The communication network is, for example, the Internet, wired communication, wireless communication or other communication media.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A driving apparatus, configured to drive a display panel, comprising:
a first dynamic adjustment circuit, configured to receive first color original data and dynamically adjust a dynamic value, wherein the first dynamic adjustment circuit changes the first color original data according to the dynamic value to obtain first color new data, and the first color new data is used to drive a first color sub-pixel of a pixel of the display panel; and
a second dynamic adjustment circuit, coupled to the first dynamic adjustment circuit to receive the dynamic value, and configured to receive second color original data, wherein the second dynamic adjustment circuit changes the second color original data according to the dynamic value to obtain second color new data, so as to compensate a brightness difference between the first color new data and the first color original data, and the second color new data is used to drive a second color sub-pixel of the pixel of the display panel.

2. The driving apparatus according to claim 1, wherein the first color original data comprises sub-pixel data corresponding to a white sub-pixel, and the second color original data comprises sub-pixel data corresponding to one of a red sub-pixel, a green sub-pixel and a blue sub-pixel.

3. The driving apparatus according to claim 1, wherein the first dynamic adjustment circuit adjusts the dynamic value according to a time curve.

4. The driving apparatus according to claim 3, wherein the first dynamic adjustment circuit determines a ratio according to the time curve, and the first dynamic adjustment circuit multiplies an offset value by the ratio to obtain the dynamic value.

5. The driving apparatus according to claim 4, wherein the offset value is a fixed real number.

6. The driving apparatus according to claim 4, wherein the offset value is related to a difference between the first color original data and the second color original data.

7. The driving apparatus according to claim 6, wherein the second color original data comprises red original data, green original data and blue original data, and the offset value is related to a difference between the first color original data and a maximum among the red original data, the green original data and the blue original data.

8. The driving apparatus according to claim 1, wherein the first dynamic adjustment circuit subtracts the first color original data by the dynamic value to obtain the first color new data, and the second dynamic adjustment circuit adds the second color original data by the dynamic value to obtain the second color new data.

9. The driving apparatus according to claim 1, wherein the second color original data comprises red original data, green original data and blue original data, and the second dynamic adjustment circuit adds the red original data by the dynamic value to obtain red new data, adds the green original data by the dynamic value to obtain green new data and adds the blue original data by the dynamic value to obtain blue new data.

10. An operation method of a driving apparatus, wherein the driving apparatus is configured to drive a display panel, the operation method comprising:
dynamically adjusting a dynamic value by a first dynamic adjustment circuit;
changing first color original data according to the dynamic value by the first dynamic adjustment circuit to obtain first color new data, wherein the first color new data is used to drive a first color sub-pixel of a pixel of the display panel;
receiving the dynamic value of the first dynamic adjustment circuit by a second dynamic adjustment circuit; and
changing second color original data according to the dynamic value by the second dynamic adjustment circuit to obtain second color new data, so as to compensate a brightness difference between the first color new data and the first color original data, wherein the second color new data is used to drive a second color sub-pixel of the pixel of the display panel.

11. The operation method according to claim 10, wherein the first color original data comprises sub-pixel data corresponding to a white sub-pixel, and the second color original data comprises sub-pixel data corresponding to one of a red sub-pixel, a green sub-pixel and a blue sub-pixel.

12. The operation method according to claim 10, wherein the operation of dynamically adjusting the dynamic value comprises:
adjusting the dynamic value according to a time curve by the first dynamic adjustment circuit.

13. The operation method according to claim 12, wherein the operation of adjusting the dynamic value according to the time curve comprises:
determining a ratio according to the time curve by the first dynamic adjustment circuit; and
multiplying an offset value by the ratio by the first dynamic adjustment circuit to obtain the dynamic value.

14. The operation method according to claim 13, wherein the offset value is a fixed real number.

15. The operation method according to claim 13, wherein the offset value is related to a difference between the first color original data and the second color original data.

16. The operation method according to claim 15, wherein the second color original data comprises red original data, green original data and blue original data, and the offset value is related to a difference between the first color original data and a maximum among the red original data, the green original data and the blue original data.

17. The operating method according to the claim 10, further comprising:
subtracting the first color original data by the dynamic value by the first dynamic adjustment circuit to obtain the first color new data; and
adding the second color original data by the dynamic value by the second dynamic adjustment circuit to obtain the second color new data.

18. The operation method according to claim 10, wherein the second color original data comprises red original data, green original data and blue original data, and the operation of obtaining the second color new data comprises:
adding the red original data by the dynamic value by the second dynamic adjustment circuit to obtain red new data;
adding the green original data by the dynamic value by the second dynamic adjustment circuit to obtain green new data; and
adding the blue original data by the dynamic value by the second dynamic adjustment circuit to obtain blue new data.
